(19) United States
(12) Patent Application Publication
(10) Pub. No.: US 2024/0027816 A1
(43) Pub. Date: Jan. 25, 2024

(54) INTERACTIVE TOUCH-SCREEN DISPLAY DEVICE WITH STATIC CHARGE DISSIPATION AND METHOD OF ASSEMBLING THE SAME

(71) Applicant: Promethean Limited, Blackburn (GB)

(72) Inventors: Paul Wareing, Garstang (GB); John Brannan, Bolton (GB); Christopher Dawson, Burnley (GB); Melanie Friar, Newton-le-Willows (GB)

(73) Assignee: Promethean Limited, Blackburn (GB)

(21) Appl. No.: 18/356,583

(22) Filed: Jul. 21, 2023

Related U.S. Application Data
(60) Provisional application No. 63/391,577, filed on Jul. 22, 2022.

(51) Int. Cl. G02F 1/1333; H05K 9/00

(52) U.S. Cl. CPC G02F 1/13338; G02F 1/133331; H05K 9/0079; G02F 2202/22

(57) ABSTRACT

An interactive touch-screen display device includes a liquid crystal layer; a conductive layer, the conductive layer being translucent and electronically grounded; a polarizer; and a glass layer, wherein the conductive layer contacts the glass layer and contacts the polarizer. Additionally, a method of assembling an interactive touch-screen display device includes creating an assembly by layering a liquid crystal layer and a polarizer. The method also includes bringing a conductive material proximate to the polarizer; creating a static charge on the conductive material to attract dust particles to the conductive material; and removing the conductive material, thereby carrying away dust particles.

### CROSS-REFERENCE TO RELATED APPLICATIONS

This application claims the benefit of U.S. Provisional Patent Application Ser. No. 63/391,577, filed Jul. 22, 2022, the entire disclosure of which is hereby incorporated herein by reference in its entirety.

### BACKGROUND

Interactive touch-screen display devices have become an important element in a variety of aspects of modern life, including education. For example, large interactive touch-screen display devices are often incorporated into educational environments (i.e., classrooms), and may incorporate features analogous to a traditional chalkboard, such as writing elements and erasers. In such cases, the interactive touch-screen display device may be provided with a thick layer of glass to protect sensitive display electronics during heavy use.

However, protective glass may introduce parallax error resulting in a difference between where a user's stylus physically touches the interactive touch-screen display device and where the user perceives the marks displayed by the interactive touch-screen display device in response to the stylus. Parallax error may be particularly detrimental for children who are learning to write on the interactive touch-screen display device, or in cases where precise marking are required.

Further, in some cases, the protective glass may collect a static charge during use, for instance due to clothing rubbing against the glass, erasers used to clear writing from the interactive touch-screen display device, or other use contact on the display device. This static charge may interrupt the interactive touch-screen display device electronics, resulting in poor image quality or unusable spots on the interactive touch-screen display device.

Accordingly, there is a need for interactive touch-screen display devices and interactive touch-screen display device assembly methods which reduce parallax errors and dissipate static charges in order to address these and other concerns.

### SUMMARY

An interactive touch-screen display device may include a liquid crystal layer; a conductive layer, the conductive layer being translucent and electronically grounded; a polarizer; and a glass layer, wherein the conductive layer contacts the glass layer and contacts the polarizer.

In an additional embodiment, a method of assembling an interactive touch-screen display device may include creating an assembly by layering a liquid crystal layer and a polarizer. The method may also include bringing a conductive material proximate to the polarizer; creating a static charge on the conductive material to attract dust particles to the conductive material; and removing the conductive material, thereby carrying away dust particles.

An interactive touch-screen display device, in various aspects, comprises a set of layers supported by a frame, the set of layers comprising: (1) a front cover glass; (2) a polarizer disposed behind the front cover glass and zero-bonded to the front cover glass; (3) a conductive layer disposed adjacent the polarizer, the conductive layer being substantially translucent and electronically grounded; and (4) a liquid crystal layer disposed on an opposing side of the polarizer from the front cover glass, wherein the conductive layer is configured to discharge a static buildup at a particle disposed between two layers of the set of layers. In some aspects, the conductive layer is disposed between the polarizer and the front cover glass. In other aspects, the conductive layer is disposed between the polarizer and the liquid crystal layer.

In various aspects, the conductive layer comprises a mesh of wires so dimensioned as to be substantially invisible to an interactive touch-screen display device user. In a particular aspect, the wires comprise at least one of indium-tin-oxide or silver. In other aspects, the conductive layer comprises poly(3,4-ethylenedioxythiophene) (PEDOT). In various aspects, the conductive layer is not connected to a power supply.

An interactive touch-screen display device in various embodiments, comprises: (1) a liquid crystal layer; (2) a conductive layer, the conductive layer being translucent and electronically grounded; (3) a polarizer; and (4) a glass layer, wherein the conductive layer contacts the glass layer and contacts the polarizer. In various aspects, the conductive layer is configured to discharge static buildup at a particle disposed between the glass layer and the polarizer. In some aspects: (1) the liquid crystal layer, the conductive layer, the polarizer, and the glass layer are sandwiched together in a clamping frame; (2) the liquid crystal layer is disposed adjacent the glass layer; (3) the conductive layer is disposed between the glass layer and the polarizer; and (4) the interactive touch-screen display device further comprises a cover glass disposed adjacent the polarizer on an opposing side of the polarizer from the conductive layer. In some aspects, the cover glass is zero-bonded to the polarizer. In various aspects, the conductive layer comprises a mesh of wires so dimensioned as to be substantially invisible to an interactive touch-screen display device user.

In particular aspects, the conductive layer comprises a mesh of wires so dimensioned as to be substantially invisible to an interactive touch-screen display device user. In a particular aspect, the wires comprise at least one of indium-tin-oxide or silver. In other aspects, the conductive layer comprises poly(3,4-ethylenedioxythiophene) (PEDOT). In various aspects, the conductive layer is not connected to a power supply.

A method of assembling an interactive touch-screen display device, the method comprising: (1) creating an assembly by layering a liquid crystal layer and a polarizer; (2) bringing a conductive material proximate to the polarizer; (3) creating a static charge on the conductive material to attract dust particles to the conductive material; and (4) removing the conductive material. In some aspects the method further comprises: (1) scanning a surface of the polarizer with a sensor; (2) determining a frequency of dust particles on the surface of the polarizer; and (3) rejecting the assembly if the frequency exceeds a threshold.

In various aspects, the method comprises placing a glass layer substantially in contact with the polarizer. In other aspects, the method comprises placing a conductive layer in contact with the polarizer; and placing a glass layer in contact with the conductive layer. In some aspects, the method is performed in a dehumidified cleanroom. In other aspects, the method comprises blowing air over the assembly.

### BRIEF DESCRIPTION OF THE DRAWINGS

Various embodiments are described below. In the course of this description, reference will be made to the accompanying drawings, which are not necessarily drawn to scale, and wherein:

FIG. 1 is an interactive touch-screen display device according to various embodiments;

FIG. 2 is a diagram of layers of an interactive touch-screen display device according to various embodiments.

FIG. 3 is a diagram of layers of an interactive touch-screen display device according to various embodiments.

FIG. 4 is a diagram of layers of an interactive touch-screen display device according to various embodiments.

FIG. 5 is a flowchart showing an example of an interactive touch-screen display device assembly method according to various embodiments.

### DETAILED DESCRIPTION

Various embodiments now will be described more fully hereinafter with reference to the accompanying drawings. It should be understood that the invention may be embodied in many different forms and should not be construed as limited to the embodiments set forth herein. Rather, these embodiments are provided so that this disclosure will be thorough and complete, and will fully convey the scope of the invention to those skilled in the art. Like numbers refer to like elements throughout. Additionally, certain elements may not be drawn according to scale.

Interactive touch-screen display devices used in an educational environment provide many benefits over traditional chalk boards. These interactive touch-screen display devices allow teachers to display presentations, while also writing on presentations in real time to add explanatory notes, example problems, and solutions. Such interactive touch-screen display devices may also copy the teacher's handwritten notes for digital reproduction and distribution to students. Further, these interactive touch-screen display devices eliminate the dust caused by traditional chalk boards, and may not require consumable materials (e.g., chalk, erasers, markers, etc.). Further, students may use these interactive touch-screen display devices during instruction, as well. Additionally, interactive touch-screen display devices may be used to display video content, mirror content from other computing device, and perform other functions that are not possible using traditional chalk or whiteboards.

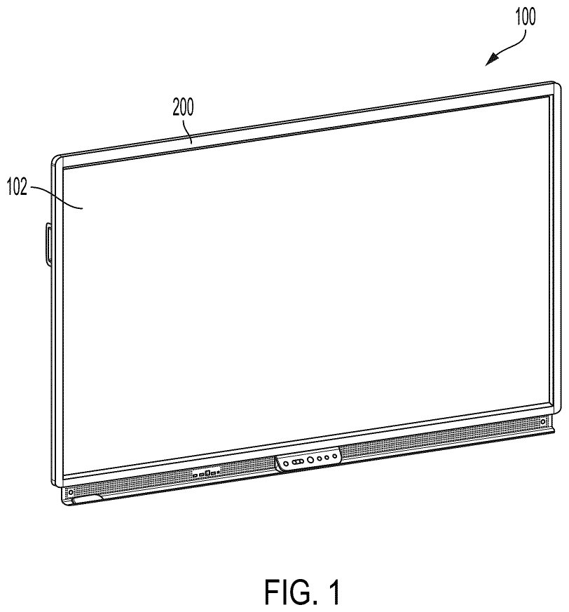

As may be understood from FIG. 1, an interactive touch-screen display device 100 (which may, for example, include any suitable interactive display device (e.g., such as any suitable Promethean ActivPanel display), according to particular embodiments, comprises: (1) an interactive display device touch surface (e.g., glass layer 102); and (2) an interactive display device bezel 200 (which may, for example, form a substantially rectangular frame about a perimeter of the glass layer 102). In some embodiments, the interactive touch-screen display device 100 is configured to display data (e.g., video data, image data, etc.). In particular embodiments, the interactive touch-screen display device 100 is configured to receive inputs via contact at the glass layer 102.

In various embodiments of the interactive touch-screen display device 100, the interactive touch-screen display device 100 may comprise any suitable touch screen device configured to receive input via contact on the glass layer 102 (e.g., via a user's finger or other body part, via a stylus or other pen-like device, etc.). For example, in various embodiments, the interactive touch-screen display device 100 comprises an infrared (e.g., or other electromagnetic wave) touch screen display (e.g., which may, for example, include a plurality of infrared emitters and detectors (e.g., one or more suitable photo receptors) at least partially embedded in the interactive display device bezel 200 of the one interactive touch-screen display device 100), or any other suitable touch screen display. In particular embodiments, the interactive touch-screen display device 100 comprises one or more processors (e.g., or other computing hardware) and memory. In such embodiments, the interactive touch-screen display device 100 may comprise a stand-alone computing device such as a wall-mounted display device (e.g., such as a touch-enabled computerized LED and/or LCD displays), etc.

In particular embodiments, the interactive touch-screen display device 100 is configured to detect a touch input at the glass layer 102 in response to detecting a break in a light grid defined by the plurality of infrared emitters and detectors. In still other embodiments, the interactive touch-screen display device 100 is configured to detect a plurality of simultaneous inputs (e.g., from a plurality of users). In various embodiments, the interactive touch-screen display device 100 is configured to enable a user to interact with one or more displayed images as the user would interact with any other computing display device (e.g., by drawing on the one or more projected images), etc. In still other embodiments, the interactive touch-screen display device 100 includes one or more computing components (e.g., one or more processors and memory) such that the interactive touch-screen display device 100 embodies a stand-alone computing device.

In some aspects, when a user is providing input at the glass layer 102, the user may apply pressure on the interactive touch-screen display device 100 (e.g., pressure against the glass layer 102). This may, for example, result from a user writing or otherwise drawing on the interactive touch-screen display device 100 in a manner similar to how the user may write or draw on a traditional chalkboard or whiteboard. In some aspects, users may apply more pressure than is required for the interactive touch-screen display device 100 to detect the input(s) at the glass layer 102, for example, because the user is providing an input force that the user may be used to providing in order to draw with chalk on a chalkboard or a marker on a whiteboard, etc.

To increase the lifetime of these interactive touch-screen display devices, a layer of glass (e.g., glass layer 102) may be installed in front of the electronics. Frequent contact at the glass layer 102 or other contact surface (e.g., with a stylus, finger or other body part, eraser, etc.), though, may result in high pressure points that could damage sensitive electronics that provide the display graphics and/or detect a position of a stylus or other implement (fingers, erasers, etc.). This layer of glass (e.g., glass layer 102) may help distribute and resist localized pressures, while also providing a scratch-resistant surface to avoid optical interruption of a displayed graphic. This layer of glass may be relatively thick (e.g., 4 millimeters or more), such as in the case of an interactive touch-screen display device with a large surface area which is primarily used at locations far away from a structural support member (e.g., a frame). This thick layer of glass and the space between the glass and the LCD display introduces a parallax error, however. Additionally, the layer of glass may, in some cases, have imperfections causing the glass to not be perfectly flat, further contributing to parallax errors. This parallax error may be particularly confusing for young users who are learning to write, as the interactive touch-screen display device may seem to display written notes at a different location than the user anticipates with respect to the displayed image. It should be noted that, although certain embodiments are discussed herein by reference to an interactive touch-screen display device in the context of an educational (e.g., classroom) environment, similar assemblies and assembly methods may be utilized for a variety of screen applications, such as tablets, phones, televisions, etc.

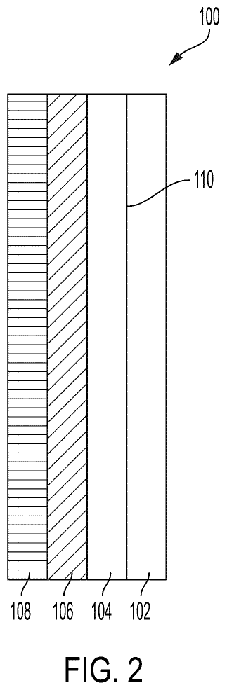

Parallax error may be reduced by reducing a distance between the display electronics and the outer surface of the glass layer adjacent to the display electronics. For example, FIG. 2 depicts a side cutaway view of an interactive touch-screen display device 100. As illustrated in FIG. 2, an interactive touch-screen display device 100 according to various embodiments may include a glass layer 102 substantially in contact with a polarizer 104 (e.g., via zero bonding method), reducing (e.g., eliminating or substantially eliminating) a distance between an outer surface (i.e., contact surface) of the glass layer 102 and a liquid crystal layer 106 and backlight 108 disposed behind the polarizer 104. By reducing the distance between the outer surface of the glass layer 102 and the liquid crystal layer 106, the parallax error causing a distortion between a touchpoint of a user's stylus and a perceived display point of a mark generated in response to the user's stylus may be reduced, improving the user's experience and ability to write on the interactive touch-screen display device with precision. In some embodiments, the interactive touch-screen display device 100 may include additional layers, such as a color layer (e.g., a red/green/blue (RGB) layer), a capacitive touch sense layer, a light diffusion layer, an additional polarizer(s), and/or electronics configured to activate sets of crystals of the liquid crystal layer 106.

Although the embodiment previously described may reduce parallax error, in some cases, dust particles, such as dust particle 110, may be trapped between the glass layer 102 and the LCD display (e.g., the polarizer 104) during assembly, for instance, in regions where gaps are formed due to imperfections in the flatness of the glass as illustrated in FIG. 2. Since the glass layer 102 and the polarizer 104 may be in contact, the glass layer 102 and the polarizer 104 may mechanically hold a dust particle in place during use. Further, in some embodiments, the dust particle 110, the glass layer 102, and the polarizer 104 may all be insulators, and the dust particle 110 may concentrate electrical charges. These may include, for example, electric charges resulting from static charge buildup originating from contact (e.g., rubbing) at the glass layer 102 by the user (e.g., using the eraser on the glass, using their hand to erase across the glass or by other rubbing motions by the user on the glass surface). The concentrated charge buildup on the dust particle may interrupt functionality of nearby liquid crystals in the liquid crystal layer 106 thereby causing crystals to change color. This, in turn, may result in black or miscolored spots on the screen when the display is displaying a light colored image, which obstruct a displayed graphic, or “always-on” spots where crystals fail to activate and to block light transmission when required to properly display a graphic. This may be particularly problematic for interactive touch-screen display devices, which may be used in place of traditional whiteboards, thereby typically displaying an always-white screen when not otherwise in use.

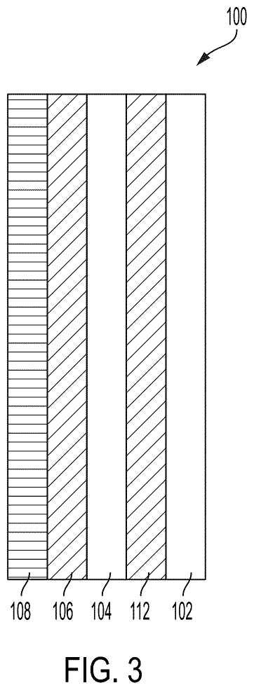

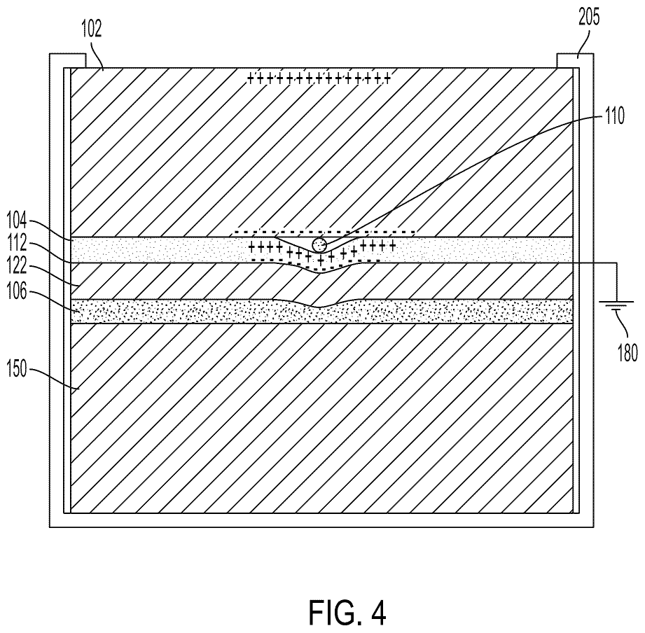

Accordingly, FIG. 3 illustrates an embodiment of the interactive touch-screen display device 100 further comprising a conductive translucent layer 112 that may dissipate charges collected on dust particles (e.g. the dust particle 110), which is then dissipated to ground. The conductive translucent layer 112 may be disposed between the glass layer 102 and the LCD (e.g., the polarizer layer 104), and may contact both the glass layer 102 and the polarizer 104. In other embodiments, the conductive layer 112 may be disposed between the polarizer and the liquid crystal layer 106. In this manner, the conductive translucent layer 112 may have a high likelihood of contacting and/or attracting dust particles, and pulling away any collected charges on the dust particles. Further, the conductive translucent layer 112 may be electronically grounded (e.g., to a frame of the interactive touch-screen display device, to a battery of the interactive touch-screen display device, or to a ground circuit) so that a buildup of charge (e.g., around the dust particle 110 such as in an air gap around the particle) may be terminated (e.g., discharged) (See e.g., FIG. 4). This may also help to avoid static charge buildup, which could otherwise build over time and spark, potentially destroying sensitive electronics of the interactive touch-screen display device. Additionally, by dissipating and/or removing collected charges, the conductive translucent layer 112 may help ensure that on/off signals are transmitted to and received by individual liquid crystals of the liquid crystal layer 106, thereby aiding in consistent and reliable functioning of the interactive touch-screen display device 100.

The conductive translucent layer 112 may be substantially translucent, as well. For example, the conductive translucent layer 112 may comprise a mesh of wires so dimensioned as to be substantially invisible to an interactive touch-screen display device user. The mesh of wires may be dimensioned to be substantially invisible by constructing the mesh with wires having a thin thickness, and/or selecting a grid spacing to transmit a substantial portion of generated light (e.g., 90%, 95%, 99%, etc. of generated light). In some embodiments, the wires may comprise indium-tin oxide and/or silver, for example. Additionally, or alternatively, the conductive translucent layer 112 may comprise a translucent conductive film, such as poly(3,4-ethylenedioxythiophene) (PEDOT). In other aspects, the conductive layer 112 may include ITO ESD. Further, the thickness of the wires and/or the film may be based on an anticipated charge removal rate (i.e., electrical current) to avoid degradation of the conductive film over time.

The conductive translucent layer 112 may be disposed at any other suitable location in the interactive touch-screen display device, as well, and the interactive touch-screen display device 100 may include multiple conductive layers. For instance, a conductive layer may be placed between the backlight 108 and the liquid crystal layer 106, and/or between any layers where charges (e.g., static charge buildup) collected on dust particles may interfere with desired functioning of electronics. In other aspects, the display device may include a plurality of conductive layers 112 (e.g., between various suitable layers), each of which are electronically grounded.

In some embodiments, the conductive translucent layer 112 may be electronically grounded and not connected to a power supply. Alternatively, the conductive translucent layer 112 may be selectively connected to a power supply, such that the conductive translucent layer 112 may be selectively charged to attract any dust particles and discharged to remove any built up charges on the dust particles. In some embodiments, the conductive translucent layer 112 may be configured to be charged only during manufacturing to attract any dust particles accumulated in a manufacturing environment, and then electronically grounded during assembly, thus helping to ensure contact between dust particles and the conductive translucent layer 112 for future charge dissipation.

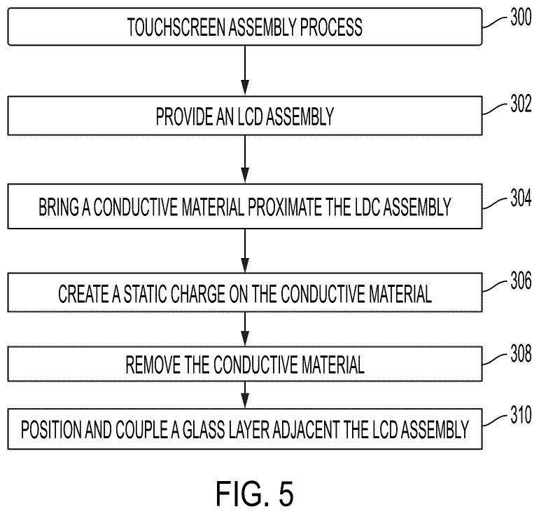

FIG. 5 illustrates an interactive touch-screen display device assembly process 300 according to various embodiments of the present disclosure. The interactive touch-screen display device assembly process 300 may be used to assemble the interactive touch-screen display device embodiments shown in FIGS. 2 and 3. For example, the interactive touch-screen display device assembly process 300 may be used to manufacture an interactive touch-screen display device with or without a conductive translucent layer, such as the conductive translucent layer 112. For instance, a supplier may wish to construct an interactive touch-screen display device without a conductive layer to reduce material costs, or a supplier may wish to construct an interactive touch-screen display device with a conductive translucent layer to improve reliability. In some embodiments, the interactive touch-screen display device assembly process 300 may be performed in a dehumidified clean room (e.g., a class 10,000/ISO-7 standard cleanroom) to substantially eliminate dust particles from becoming trapped between the LCD (e.g., the polarizer layer 104) and the touch surface (e.g., the glass 102).

In various aspects, the inclusion of particles between the LCD assembly and glass layer following assembly may, in addition to the potential electro-static disturbance discussed above, further cause a local distortion of the front glass layer (e.g., and the underlying LCD assembly) at a location local to any particles. These local distortions may result in a mechanical pressing through the assembly (e.g., when a user is contacting the display screen at the location of the particle) such that the underlying LCD cell is slightly distorted (e.g., crushed), resulting in inaccurate color display at the location of the underlying LCD cell. This mechanical pressure may, for example, affect the polarization rotation of particular LCD cells such that the switched on LCD cell transmits less visible light (e.g., resulting in a ‘black’ spot). This mechanical distortion can further lead to black spots or other color irregularities.

In a particular example, as may be understood from FIG. 4, a particle (e.g., a particle of at least 100 micrometers) may become trapped between the cover glass layer and the LCD assembly (e.g., the polarizer 104) during assembly. Because the cover glass layer is clamped to the LCD assembly (e.g., via support frame), the frame places the cover glass layer and the LCD assembly under compression. Rubbing of the cover glass layer (e.g., as discussed above) may cause a static charge on the surface of the cover glass. The static charge may then cause electrical polarization of the cover glass and the polarizer 104, which may, for example, introduce a charge across the gap around the particle. The resulting opposing charges may then attract the cover glass layer toward the polarizer 104 such that the polarizer 104 droops over the particle. This deformation may then cause a localized force which reduces the vertical extent of the LCD cell such that the polarization rotation of the LCD cell is reduced at that location. The conductive layer 112, in any embodiment described herein, may be operatively coupled to a ground 180.

In the embodiment shown FIG. 4, the interactive display device 100 may include a frame 205 that clamps the various component layers of the display together. These layers may include, for example, a cover glass 102, a polarizer 104, a conductive layer 112, a front glass 122, a liquid crystal display cell 106, one or more other LCD components 150, and or/any other suitable components.

In particular embodiments, the display may include other LCD components 150 (e.g., a color layer (e.g., a red/green/blue (RGB) layer), a capacitive touch sense layer, a light diffusion layer, an additional polarizer(s), and/or electronics configured to activate sets of crystals of the liquid crystal layer 106, etc.).

In some embodiments, these black spots and/or color distortions may encompass multiple pixels on the display, in a way that is visible to the human eye (e.g., and undesirable to an interactive touch-screen display user). In other words, embodiments that include a conductive layer as described above (e.g., which may reduce and/or substantially eliminate spotting that results from electro-static charge build up) may nevertheless experience inaccurate color (e.g., in the form of black spots) local to a dust particle sandwiched between the cover glass layer and LCD assembly.

As such, it may be desirable to sufficiently reduce an incidence of particles between the LCD assembly and glass layer during assembly (i.e., to reduce and/or substantially eliminate the spotting that results from the particle presence). This is particularly true for ‘larger’ particles (e.g., particles that are at least about 100 micrometers in size), which may result in a greater localized distortion of the front glass layer or LCD assembly (e.g., a localized distortion sufficient to result in a mechanical pressing that affects the underlying LCD cell). In some aspects, a distortion of at least about 0.1 micrometers at the location of a particle between the LCD assembly and cover glass layer may be sufficient to distort or crush the underlying LCD assembly, resulting in an at least temporary ‘black spot’ or other localized color distortion.

Various embodiments of an interactive touch-screen display device assembly process are described below. In various aspects, the process may reduce and/or substantially eliminate the presence of particles (e.g., dust particles) between an assembled LCD assembly and cover glass layer within a frame during assembly of the interactive touch-screen display device. In various embodiments, the process may particularly reduce and/or substantially eliminate particles of a size greater than 100 micrometers. In particular other embodiments, the process may further include the introduction of a conductive layer as described above. In such embodiments, the use of the conductive layer may eliminate and/or substantially reduce an incidence of black sports resulting from static charge buildup from any particles that nevertheless persist between the LCD assembly and cover glass layer and/or polarizer (e.g., particles smaller than 100 micrometers and other particles).

The interactive touch-screen display device assembly process 300 begins with step 302 by providing an assembly that includes at least a liquid crystal layer. In other aspects, the assembly may further comprise a polarizer. The LCD assembly provided at Step 302 may include additional layers, as well, such as a backlight, RGB layer, support layers (e.g., glass layers), etc. In some aspects, the LCD assembly may include one or more conductive layers as described herein. The layers may be laid flat on top of each other, or any other suitable orientation. For instance, the liquid crystal layer may be laid flat, followed by the polarizer and any other suitable layers, such that the polarizer is on top of the liquid crystal layer. In various embodiments, the LCD layer/assembly may be provided by a third party supplier for assembly into an interactive touch-screen display device.

In particular aspects, during an interactive touch-screen display device assembly process 300, the process may involve placing the LCD assembly adjacent to a cover glass layer and coupled to the cover glass layer using any suitable zero bonding method or optical bonding method. As part of the assembly process, the LCD assembly may be placed on a rear cover of the interactive touch-screen display device (e.g., in a flat orientation) and coupled to the rear cover. The process may then involve bonding (e.g., using any suitable technique) the cover glass layer to the LCD assembly before attaching the front frame of the interactive touch-screen display device to the rear cover, sandwiching the LCD assembly and cover glass layer together between the rear cover and the front frame. Alternatively, the process may involve positioning the cover glass layer adjacent the front frame before dropping the LCD assembly and rear cover on top of the cover glass layer and securing the rear cover to the front frame. In this way, using either assembly technique, the cover glass layer is positioned substantially adjacent/against the LCD assembly, which may result in particles (e.g., dust particle 110) being trapped between the LCD assembly and the cover glass layer (i.e., as discussed herein). As such, additional assembly techniques may include one or more additional steps (such as those discussed below), in order to reduce an incidence of particles being trapped between the LCD assembly and cover glass layer following and/or during assembly.

At step 304, for example, the interactive touch-screen display device assembly process 300 may include bringing a conductive material proximate to the LCD assembly (e.g., the outer face of the LCD assembly) prior to placing the LCD assembly adjacent the cover glass layer. The conductive material may be, e.g., a foil, block, sphere, or other shape, and may comprise aluminum, copper, iron, etc. The conductive material may be connected to a power supply, and the interactive touch-screen display device assembly process 300 may, at step 306, include creating a static charge on the conductive material using the power supply. The static charge may then attract dust particles from the surface of the LCD assembly to the surface of the conductive material, and the conductive material may be removed at step 308, thereby carrying away any attracted dust particles. In some aspects, the process may include using any suitable statically charged material configured for attracting dust. In some aspects, the method may include wiping the charged material over the LCD assembly prior to adhering the glass. Step 304 may also include passing air over the assembly (e.g., a stream of heated gas) to blow away particles. In other aspects the same process described with respect to steps 304 and 306 may be additionally or alternatively performed on the glass layer. In still other aspects, the process of steps 304 and 306 may be performed using a conductive material positioned between the LCD assembly and glass layer prior to (e.g., immediately prior to) sandwiching the LCD assembly and glass layer together. In this way, the process may reduce and/or minimize a number of particles on the co-facing surfaces of the LCD assembly and glass layer prior to (e.g., substantially immediately prior to) sandwiching them together.

In some embodiments, the interactive touch-screen display device assembly process 300 may also include a scanning process to detect interactive touch-screen display devices that still hold dust particles. For instance, the interactive touch-screen display device assembly process 300 may include scanning a surface (e.g., the exposed surface of the LCD assembly) with a sensor, such as an optical (e.g., light-based) sensor. For instance, the sensor may emit light of a certain wavelength capable of illuminating dust particles, and the sensor may detect light reflected from a dust particle. The sensor may be moved mechanically around the polarizer, such as in a raster pattern. Based on readings from the sensor, a frequency of dust particles on the surface of the polarizer may be determined, and the interactive touch-screen display device may be rejected if the frequency exceeds a threshold. Alternatively, the interactive touch-screen display device may be passed by the conductive material again to remove additional dust particles and re-scanned until the frequency of dust particles falls below a threshold.

The interactive touch-screen display device assembly process 300 may also include placing a glass layer on the assembly, for instance after removing dust from the surface of the polarizer. The glass layer may be placed substantially in contact with an outer surface of the LCD assembly in certain embodiments. Alternatively, the interactive touch-screen display device assembly process 300 may include placing a conductive layer in contact with the LCD assembly, and placing a glass layer in contact with the conductive layer, based on desired reliability and production costs.

### CONCLUSION

Although embodiments above are described in reference to various data storage and exchange systems, it should be understood that various aspects of the system described above may be applicable to other types of systems, in general.

While this specification contains many specific embodiment details, these should not be construed as limitations on the scope of any invention or of what may be claimed, but rather as descriptions of features that may be specific to particular embodiments of particular inventions. Certain features that are described in this specification in the context of separate embodiments may also be implemented in combination in a single embodiment. Conversely, various features that are described in the context of a single embodiment may also be implemented in multiple embodiments separately or in any suitable sub-combination. Moreover, although features may be described above as acting in certain combinations and even initially claimed as such, one or more features from a claimed combination may in some cases be excised from the combination, and the claimed combination may be directed to a sub-combination or variation of a sub-combination.

Similarly, while operations may be described in a particular order, this should not be understood as requiring that such operations be performed in the particular order described or in sequential order, or that all described operations be performed, to achieve desirable results. In certain circumstances, multitasking and parallel processing may be advantageous. Moreover, the separation of various system components in the embodiments described above should not be understood as requiring such separation in all embodiments, and it should be understood that the described program components and systems may generally be integrated together in a single software product or packaged into multiple software products.

Many modifications and other embodiments of the invention will come to mind to one skilled in the art to which this invention pertains having the benefit of the teachings presented in the foregoing descriptions and the associated drawings. Therefore, it is to be understood that the invention is not to be limited to the specific embodiments disclosed and that modifications and other embodiments are intended to be included within the scope of the appended claims. Although specific terms are employed herein, they are used in a generic and descriptive sense only and not for the purposes of limitation.

What is claimed is:

1. An interactive touch-screen display device comprising a set of layers supported by a frame, the set of layers comprising:
a front cover glass;
a polarizer disposed behind the front cover glass and zero-bonded to the front cover glass;
a conductive layer disposed adjacent the polarizer, the conductive layer being substantially translucent and electronically grounded; and
a liquid crystal layer disposed on an opposing side of the polarizer from the front cover glass, wherein the conductive layer is configured to discharge a static buildup at a particle disposed between two layers of the set of layers.

2. The interactive touch-screen display device of claim 1, wherein the conductive layer is disposed between the polarizer and the front cover glass.

3. The interactive touch-screen display device of claim 1, wherein the conductive layer is disposed between the polarizer and the liquid crystal layer.

4. The interactive touch-screen display device of claim 1, wherein the conductive layer comprises a mesh of wires so dimensioned as to be substantially invisible to an interactive touch-screen display device user.

5. The interactive touch-screen display device of claim 4, wherein the wires comprise at least one of indium-tin-oxide or silver.

6. The interactive touch-screen display device of claim 1, wherein the conductive layer comprises poly(3,4-ethylenedioxythiophene) (PEDOT).

7. The interactive touch-screen display device of claim 1, wherein the conductive layer is not connected to a power supply.

8. An interactive touch-screen display device comprising:
a liquid crystal layer;
a conductive layer, the conductive layer being translucent and electronically grounded;
a polarizer; and
a glass layer, wherein the conductive layer contacts the glass layer and contacts the polarizer.

9. The interactive touch-screen display device of claim 8, wherein:
the liquid crystal layer, the conductive layer, the polarizer, and the glass layer are sandwiched together in a clamping frame;
the liquid crystal layer is disposed adjacent the glass layer;
the conductive layer is disposed between the glass layer and the polarizer; and
the interactive touch-screen display device further comprises a cover glass disposed adjacent the polarizer on an opposing side of the polarizer from the conductive layer.

10. The interactive touch-screen display device of claim 8, wherein the cover glass is zero-bonded to the polarizer.

11. The interactive touch-screen display device of claim 8, wherein the conductive layer comprises a mesh of wires so dimensioned as to be substantially invisible to an interactive touch-screen display device user.

12. The interactive touch-screen display device of claim 11, wherein the wires comprise at least one of indium-tin-oxide or silver.

13. The interactive touch-screen display device of claim 11, wherein the conductive layer comprises poly(3,4-ethylenedioxythiophene) (PEDOT).

14. The interactive touch-screen display device of claim 8, wherein the conductive layer is not connected to a power supply.

15. A method of assembling an interactive touch-screen display device, the method comprising:
creating an assembly by layering:
a liquid crystal layer; and
a polarizer;
bringing a conductive material proximate to the polarizer;
creating a static charge on the conductive material to attract dust particles to the conductive material; and
removing the conductive material.

16. The method of claim 15, further comprising:
scanning a surface of the polarizer with a sensor;
determining a frequency of dust particles on the surface of the polarizer; and
rejecting the assembly if the frequency exceeds a threshold.

17. The method of claim 15, further comprising placing a glass layer substantially in contact with the polarizer.

18. The method of claim 15, further comprising:
placing a conductive layer in contact with the polarizer; and
placing a glass layer in contact with the conductive layer.

19. The method of claim 15, wherein the method is performed in a dehumidified cleanroom.

20. The method of claim 15, further comprises blowing air over the assembly.
